(19) United States
(12) Patent Application Publication
(10) Pub. No.: US 2014/0117820 A1
(43) Pub. Date: May 1, 2014

(54) PROTECTIVE CASE OF ELECTRONIC DEVICE

(71) Applicant: CHIA-YING HUNG, KAOHSIUNG CITY (TW)

(72) Inventor: CHIA-YING HUNG, KAOHSIUNG CITY (TW)

(21) Appl. No.: 13/661,479

(22) Filed: Oct. 26, 2012

(51) Int. Cl. H05K 5/03

(52) U.S. Cl. 312/223.1

(57) ABSTRACT

A protective case of electronic device comprises a case body and a flexible member. The flexible member has its first end connected with the case body and its second end being in free state. A first combining portion is provided at the second end of the flexible member, and a second combining portion corresponding to the first combining portion is provided on the case body. By means of combination between the first combing portion and the second combining portion, the second end of the flexible member is fixed on the case body and an interlayer is formed between the case body and the flexible member for receiving personal stuffs. Furthermore, as the flexible member itself is flexible, it can be wound and then fixed to form a support structure or to wind and accommodate earphone wire.

### BACKGROUND OF THE INVENTION

1. Field of the Invention

The present invention relates to a protective case of electronic device, more particularly to a case which is encased on the outside of an electronic device such as handphone, PDA, i-Pad©, i-Pod© or i-Phone©, so as to protect these electronic devices from damaging.

2. Brief Description of Prior Art

Generally, electronic devices such as smartphone, i-Pad, i-Phone, PDA, Notebook PC, MP3, MP4 etc., have their housing made by plastics and subjected to paint baking processing. In order to avoid paint baking surface from damaging, users often apply protective cases on the exteriors of these electronic devices.

A document I of a Taiwanese Patent Gazette No. I 362913 entitled “Protective Case for Mobile Electronic Device” and publicized on 21 Apr., 2012 is herein cited. The protective case comprises a frame and a protective lid which are combined to form an accommodation space for receiving mobile electronic device; a turnover structure having a pair of sliding blocks opposite to each other and separately fixed at corresponding positions of the opposite two sides of the protective lid; the frame has U shape sliding grooves separately provided at opposite sides of the protective lid which is movably connected with the frame by the turnover structure. The pair of sliding blocks are slidably engaged in the U shape grooves correspondingly, so as to selectively cover the screen of the mobile electronic device and the operation panel, or to be overturned to the back surface of the mobile electronic device.

However, the document I is simply to provide protection for electronic device, and is unable to place an object in the protective case or to support electronic device in standing state.

A document II is a Taiwanese New Utility Patent Gazette No. M 430795 entitled “Protective Case” and publicized on 1 Jun., 2012. The protective case comprises a first housing and a second housing, and the second housing is detachably engaged with the first housing. A space is formed between the first housing and the second housing for receiving an electronic device.

Similarly, the document II is simply to provide protection for electronic device, and possesses no associated structure for storing an object except the electronic device in the protective case or support the electronic device into standing state.

### SUMMARY OF INVENTION

The main object of the present invention is to provide a protective case for electronic device which, in addition to provide protection for electronic device, can further provide accommodation for an object except the electronic device and support for the electronic device so that the electronic device can be present in vertically standing state. Even, the support structure can be provide to wind and accommodate earphone wire so as to further increase one more function of the protective case.

The main object and the effect of the present invention can be achieved by the following specific technical means:

A protective case of electronic device, comprising a case body and a flexible member, the flexible member having its first end connected with the case body and its second end being in free state; a first combining portion being provided at the second end of the flexible member, and a second combining portion corresponding to the first combining portion being provided on the case body. By means of combination between the first combing portion and the second combining portion, the second end of the flexible member is fixed on the case body and an interlayer is formed between the case body and the flexible member for receiving personal stuffs. Furthermore, as the flexible member itself is flexible, it can be curled and then fixed to form a support structure or to wind and accommodate earphone wire.

In the abovementioned protective case, the tail of the second end of the flexible member is provided with a positioning portion, and at least one positioning hole is provided on the flexible member for inserting and fixing the flexible member therein after the curling thereof.

In the abovementioned protective case, a projecting rib is provided on the positioning portion for inserting into the positioning portion so as to form firm locking and positioning therebetween.

In the abovementioned protective case, the case body and the flexible member of the protective case are formed as one undetacheable integral whole.

In the abovementioned protective case, the case body and the flexible member of the protective case are separately independent members and are assembled into an integrally whole. A frame portion for accommodation of electronic device is integrally connected to one side of the flexible member. The case body is a housing, and the frame portion of the flexible member is correspondingly assembled in the case body, while the second combining portion is provided at the back side of the case body.

In the abovementioned protective case, a recessed area is further provided on the back side of the case body, and the second combining portion is disposed in the recessed area. The recessed area is useful for placement of an object.

In the abovementioned protective case, the object is certificates, credit cards, ATM cards, coins or banknotes carried on to one person.

### BRIEF DESCRIPTION OF THE DRAWINGS

FIG. 1 is a perspective view of the appearance of the protective case of electronic device of the first embodiment of the present invention.

FIG. 2 is a schematic view showing that an electronic device incorporated within a protective case is placed in vertically standing state on a plane by a user.

FIG. 3 is a schematic view showing that when an earphone is unused and is to be stored;

FIG. 4 is a perspective exploded view showing the protective case of electronic device of the second embodiment of the present invention.

FIG. 5 is a perspective assembly view showing the protective case of electronic device of the second embodiment of the present invention;

FIG. 6 is a schematic view showing that an object is to be stored in the interlayer formed between the case body and the flexible member;

### DETAILED DESCRIPTION OF PREFERRED EMBODIMENT

The objects, the technical contents and the expected effect of the present invention will become more apparent from the detailed description of the preferred embodiments in conjunction with the accompanying drawings.

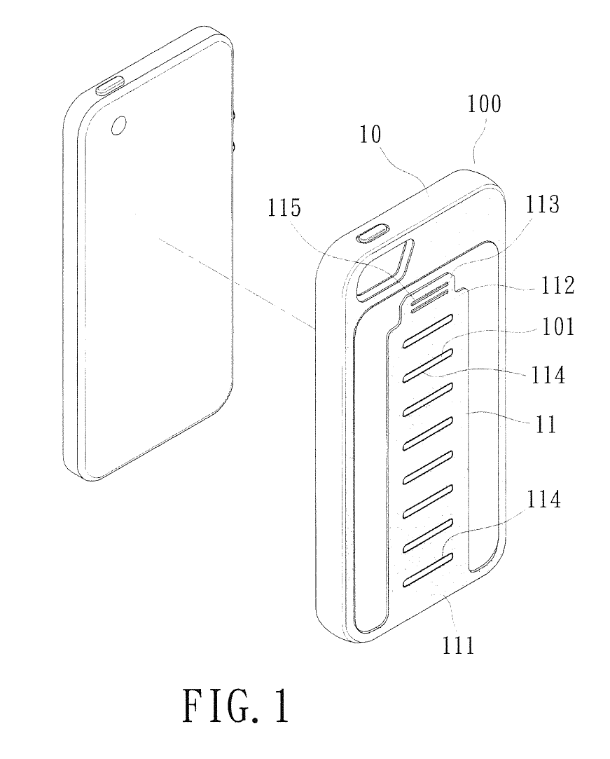

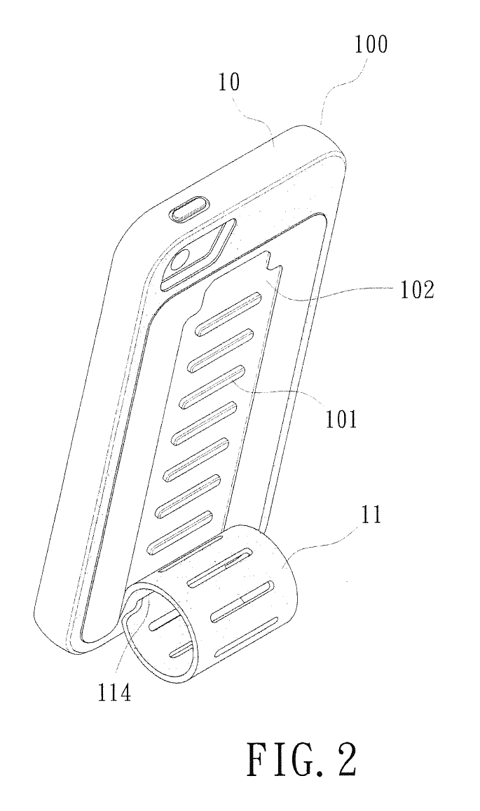

Referring to FIG. 1, the protective case 100 of electronic device of the first preferred embodiment of the present invention comprises a case body 10 and a flexible member 11. The frame of the case body 10 and the flexible member 11 are combined together by insert molding process to form an accommodation space for receiving a mobile phone. The first end 111 of the flexible member 11 is combined with the case body 10, and the second end 112 thereof is in free state. The tail of the second end 112 of the flexible member 11 is provided with a positioning portion 113, and at least one first combining portion 114 is provided on the flexible member 11. In this embodiment, the first combining portion 114 is a through hole. Referring to FIG. 2, after curling the flexible member 11, the flexible member 11 is inserted into the first combining portion 114 by the positioning portion 113 so as to hold on the curling state of the flexible member 11, and the protective case 100 can be supported by the curled flexible member 11 to form standing state in use. Preferably, a projecting rib 115 is provided on the positioning portion 113 for inserting and engaging into the first combining portion 114, so that the curling state of the flexible member 11 can be held on in more stable manner. The back side of the case body 10 has a second combining portion 101 corresponding to the first combining portion 114 of the flexible member 11. In this embodiment, the second combining portion 101 is a protruding block. By the engagement between the first combining portion 114 and the second combining portion 101, the second end 112 of the flexible member 11 is fixed on the case body 10.

FIG. 2 is a schematic view showing that an electronic device incorporated within a protective case 100 is placed in vertically standing state on a plane by a user. The flexible member 11 is curled backward and the positioning portion 113 at the tail of the second end 112 is inserted into a certain first combining portion 114. As the projecting rib 115 is provided on the positioning portion 113, the positioning portion 113 is in snap-fit engagement in the first combining portion 114 so that the curling state of the flexible member 11 can be retained in stable manner. Therefore, a support surface is formed by the bottom face of the protective case 100 and the flexible member 11 after curling, so as to support the protective case 100 into vertically standing state in use.

According to the abovementioned protective case 100, a recessed area 102 corresponding to the shape of the flexible member 11 is provided on the back side of the case body 10, so as to provide insertion and accommodation for the flexible member 11, to maintain leveling of the back side of the protective case 100, and to allow the second combining portion 101 to be disposed within the recessed area 102.

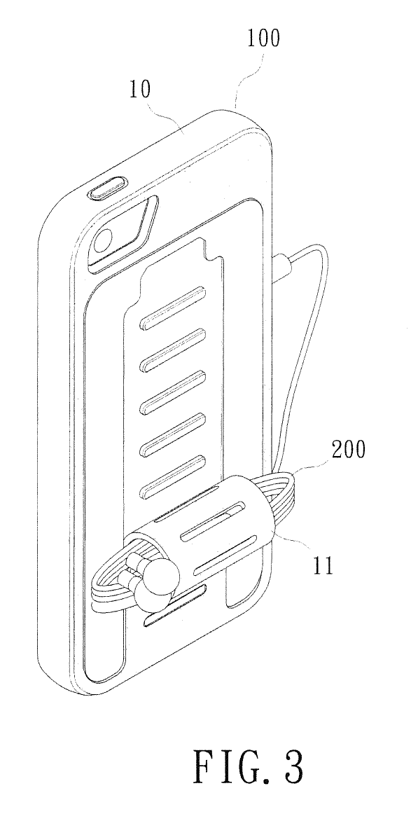

Referring to FIG. 3, when the earphone 200 is not used and is to be stored, the earphone 200 can be wound and tied with the flexible member 11, and the positioning portion 113 on the second end 112 of the flexible member 11 is inserted into any first combining portion 114 so as to fix the tied earphone 200 in place. The positioning portion 113 can be adjusted according to the final shape of the wire of the earphone 200 after winding so as to be inserted into a certain first combining portion 114, so that the earphone 200 can be stored and fixed in secure manner.

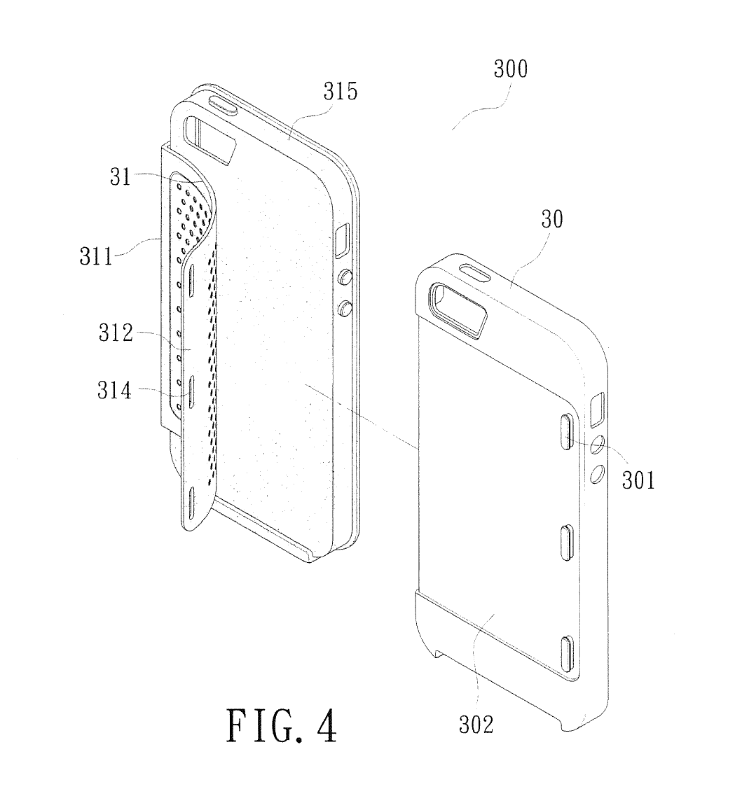

Referring to FIG. 4, a protective case 300 of electronic device of the second preferred embodiment of the present invention comprises a case body 30 and a flexible member 31. The first end 311 of the flexible member 31 is combined with the case body 30, and the second end 312 thereof is in free state. At least one first combining portion 314 is provided on the flexible member 31. In this embodiment, the first combining portion 314 is a through hole. The back side of the case body 30 has a second combining portion 301 corresponding to the first combining portion 314 of the flexible member 31. In this embodiment, the second combining portion 301 is a protruding block. By the engagement between the first combining portion 314 and the second combining portion 301, the second end 312 of the flexible member 31 is fixed on the case body 30.

Basically, this embodiment is similar to the protective case 100 of mobile electronic device of the first embodiment. The main difference lies in that the case body 30 of the protective case 300 of this embodiment and the flexible member 31 are separately independent members and are assembled together to form integrally as a whole. A frame portion 315 for accommodation of an electronic device is integrally connected to the first end 311 of the flexible member 31. The case body 30 is a housing, and the frame portion 315 of the flexible member 31 is correspondingly assembled in the case body 30. Additionally, the flexible member 11 of the first embodiment has narrower width, while the flexible member 31 of the first embodiment is wider.

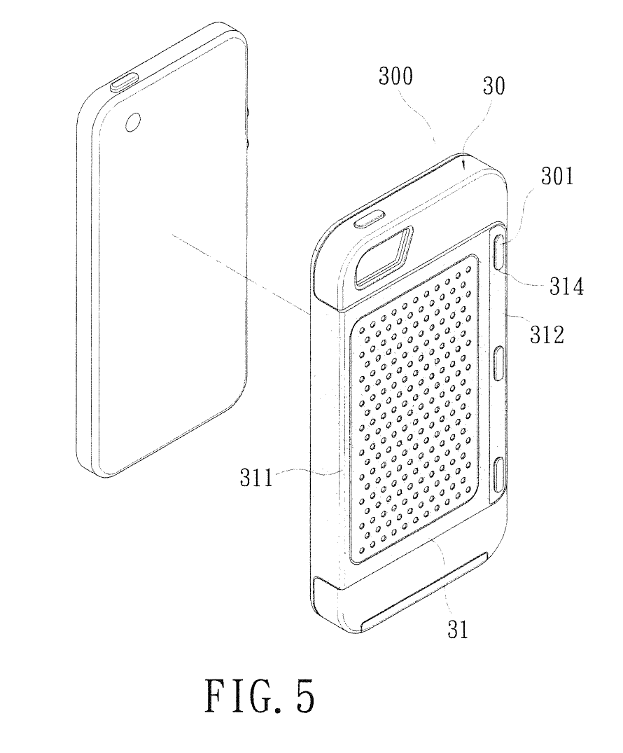

Referring to FIG. 5, as the back side of the case body 30 is similarly provided with a recessed area 302 corresponding to the shape of the flexible member 31, the leveling of the back side of the protective case 300 can be maintained, and the second combining portion 301 of the case body 30 can be disposed in the recessed area 302. In this manner, an inter layer is formed between the case body 30 and the flexible member 31, and personal stuffs such as certificates, credit cards. ATM cards, coins or banknotes are stored in the interlayer.

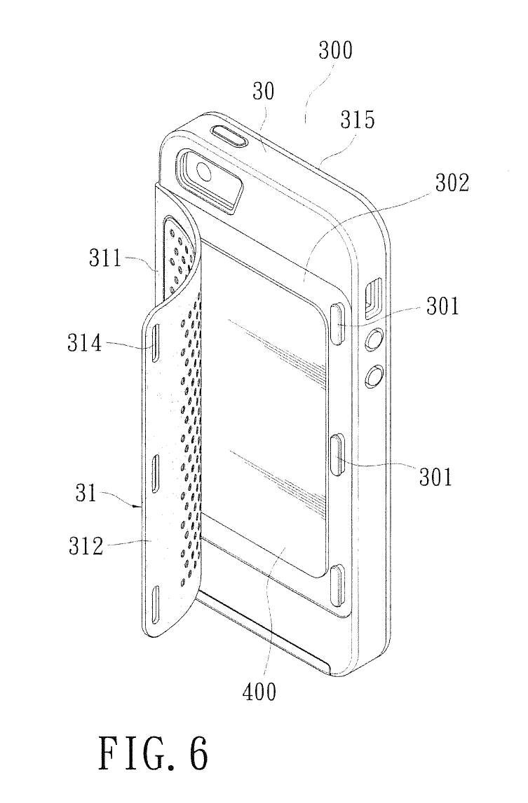

Referring to FIG. 6, when users want to store an object 400 in the interlayer formed between the case body 30 and the flexible member 31, the first combining member 314 of the flexible member 31 can be detached from the engagement with the second combining portion 301 of the case body 30 so as to allow the second end 312 of the flexible member 31 present in free state. After the object 400 is placed into the recessed area 302 of the case body 30, the first combining member 314 is engaged with the second combining portion 301 so that the second end 312 of the flexible member 31 can be fixed on case body 30. In this manner, the object 400 can be fixed in the interlayer formed between the case body 30 and the flexible member 31.

While the abovementioned embodiments of the present invention have been described in details, these are only a part of the implementation of the present invention which are not intended to limit the scope of the present invention. Variations and modifications without departing from the spirit and scope of the present invention are considered still to be within the scope of the present invention.

1. A protective case of electronic device, comprising a case body and a flexible member, said flexible member having its first end connected with said case body and its second end being in free state; a first combining portion being provided at the second end of said flexible member, and a second combining portion corresponding to said first combining portion being provided on said case body.

2. The protective case of electronic device as claimed in claim 1, wherein said flexible member has a positioning portion provided on its second end's tail, said positioning portion being engaged with said first combining portion after curling of said flexible member.

3. The protective case of electronic device as claimed in claim 2, wherein a projecting rib is provided on said positioning portion.

4. The protective case of electronic device as claimed in claim 1, wherein said case body of said protective case and said flexible member are integrally formed as a whole.

5. The protective case of electronic device as claimed in claim 1, wherein said case body of said protective case and said flexible member are separately independent members and are assembled together as a whole.

6. The protective case of electronic device as claimed in claim 5, wherein a frame portion for accommodation of electronic device is integrally connected to one side of said flexible member, said case body being a housing, and said frame portion of said flexible member being correspondingly assembled in said case body, while said second combining portion being provided at the back side of said case body.

7. The protective case of electronic device as claimed in claim 5, wherein a recessed area is provided on the back side of said case body.

8. The protective case of electronic device as claimed in claim 5, wherein said second combining portion is disposed in said recessed area.

9. The protective case of electronic device as claimed in claim 1, wherein a recessed area is provided on the back side of said case body.

10. The protective case of electronic device as claimed in claim 9, wherein said second combining portion is disposed in said recessed area.

11. The protective case of electronic device as claimed in claim 3, wherein said case body of said protective case and said flexible member are integrally formed as a whole.

12. The protective case of electronic device as claimed in claim 11, wherein a recessed area is provided on the back side of said case body.

13. The protective case of electronic device as claimed in claim 12, wherein said second combining portion is disposed in said recessed area.
